(19) United States
(12) Patent Application Publication
(10) Pub. No.: US 2012/0076246 A1
(43) Pub. Date: Mar. 29, 2012

(54) AUTOMATIC GAIN CONTROL DEVICE AND ELECTRONIC DEVICE

(75) Inventors: Eiji Okada, Osaka (JP); Satoshi Tsukamoto, Osaka (JP); Yasuo Oba, Shiga (JP); Takaharu Saeki, Osaka (JP)

(73) Assignee: Panasonic Corporation, Osaka (JP)

(21) Appl. No.: 13/309,077

(22) Filed: Dec. 1, 2011

Related U.S. Application Data
(63) Continuation of application No. PCT/JP2010/006952, filed on Nov. 29, 2010.

(30) Foreign Application Priority Data
Dec. 15, 2009 (JP) 2009-283794

(51) Int. Cl. H03G 3/20; H04N 5/455; H04L 27/06

(52) U.S. Cl. 375/340; 330/127

(57) ABSTRACT

An automatic gain control device includes amplifiers cascaded, each having a variable gain; level measurement portions respectively corresponding to the amplifiers, where each of the level measurement portions measures a level of an output signal of a corresponding one of the amplifiers in a level measurement period indicated by a level measurement signal; error calculators respectively corresponding to the level measurement portions, where each of the error calculators compares a level measured by a corresponding one of the level measurement portions with a threshold which is set so that a corresponding one of the amplifiers will not saturate, and outputs a comparison result as an error signal; a gain computation section which updates one of the gains of the amplifiers at a time corresponding to a gain update signal, based on the error signals; and an operation controller which generates the level measurement signal and the gain update signal.

### CROSS-REFERENCE TO RELATED APPLICATION

This is a continuation of PCT International Application PCT/JP2010/006952 filed on Nov. 29, 2010, which claims priority to Japanese Patent Application No. 2009-283794 filed on Dec. 15, 2009. The disclosures of these applications including the specifications, the drawings, and the claims are hereby incorporated by reference in its entirety.

### BACKGROUND

The present disclosure relates to automatic gain control (AGC) devices in devices which receive high frequency signals.

Mobile phones and radio receivers for television and radio broadcast etc. generally require high dynamic ranges. Thus, AGC devices having gain change functionality have been used. For example, International Publication No. WO 2002/080399 (Patent Document 1) describes an AGC device which controls the gain of an amplifier based on a filtered signal.

### SUMMARY

However, the configuration of Patent Document 1 uses a signal which is band limited by a filter to determine the gain of an amplifier, and accordingly, when the desired signal level is unchanged and the interference signal level increases after gain control has converged, the output level of the amplifier may exceed an upper limit.

The reason is that, as the difference between the frequencies of the interference signal and of the desired signal increases, the interference signal is attenuated more by the filter, and therefore, even when the interference signal level is higher than the desired signal level at the input of an antenna, the interference signal level may be sufficiently lower than the desired signal level at the output of the filter. In such a case, the increase in the interference signal level cannot be correctly detected from the output of the filter, and thus gain adjustment cannot be performed.

In a receiver for a stationary device, since reception conditions for radio waves do not change, once the gain is adjusted from the maximum or minimum gain to converge on a value upon powering up or changing channels, there is no need to change the gain after the convergence. Meanwhile, in a receiver for a mobile device or an in-car device, reception conditions changes constantly, and thus, as described above, the output level of the amplifier often exceeds the upper limit by the effects of an interference signal, thereby causing the reception performance to be degraded.

Also, when the interference signal level decreases, the decrease of the interference signal level cannot be correctly detected from the filter output. In general, since a higher gain is preferable in order to improve noise performance, it is preferable that the gain be increased when the interference signal level is decreased. However, unless the decrease of the interference signal level can be detected, the gain cannot be increased. Thus, a change in reception conditions may prevent an appropriate control of the gain of the amplifier.

Various embodiments may be advantageous in providing an AGC device capable of controlling the gain of a receiver in a suitable manner even when the reception conditions change.

An automatic gain control device according to an example embodiment of the present invention includes a plurality of amplifiers cascaded, each having a variable gain, a plurality of level measurement portions respectively corresponding to the plurality of amplifiers, where each of the plurality of level measurement portions is configured to measure a level of an output signal of a corresponding one of the amplifiers in a level measurement period indicated by a level measurement signal, a plurality of error calculators respectively corresponding to the plurality of level measurement portions, where each of the plurality of error calculators is configured to compare a level measured by a corresponding one of the level measurement portions with a first threshold which is set so that a corresponding one of the amplifiers will not saturate, and to output a comparison result as an error signal, a gain computation section configured to update one of the gains of the plurality of amplifiers at a time corresponding to a gain update signal, based on the error signals output from the respectively corresponding error calculators, and an operation controller configured to generate the level measurement signal and the gain update signal based on a part of the error signals output from the plurality of error calculators.

Thus, the gain of each amplifier is controlled based on the level of the output signal thereof, and thus the output signal of each amplifier can be adjusted to a suitable level depending on the reception conditions. Moreover, the gains of the plurality of amplifiers are not simultaneously updated, but the gains of the amplifiers are updated one by one, thereby allowing the control to stably converge.

An electronic device according to an example embodiment of the present invention includes a receiver having the automatic gain control device, and a demodulator configured to demodulate a signal amplified by the automatic gain control device, and to output a demodulated signal, a signal processor configured to perform predetermined signal processing on the demodulated signal, and to output a processed signal, and an output section configured to, at least display video represented by the signal which has been processed by the signal processor, or output audio represented by the signal which has been processed by the signal processor.

The automatic gain control device according to the example embodiment of the present invention can suitably control the gain and adjust the output signal of each amplifier to a suitable level regardless of reception conditions and device variations. The dynamic range of a receiver using such an automatic gain control device can be effectively utilized, thereby allowing the reception performance of the receiver to be improved.

### BRIEF DESCRIPTION OF THE DRAWINGS

FIG. 1 is a block diagram illustrating an example configuration of an AGC device according to an embodiment of the present invention.

FIG. 2 is a flow chart illustrating an example flow of a process of the AGC device of FIG. 1.

FIG. 3 is a flow chart illustrating step 276 of FIG. 2 in more detail, in which the next gain to be set is calculated.

FIG. 4 is a timing diagram illustrating an example of the input and output signals of the level measurement portions and of the error calculators of FIG. 1.

FIG. 5 is a block diagram illustrating an example configuration of the level measurement portions of FIG. 1.

FIG. 6 is an illustrative diagram which illustrates the count value etc. in the level measurement portion of FIG. 5.

FIG. 7 is a block diagram illustrating a variation of the level measurement portion of FIG. 5.

FIG. 8 is a timing diagram illustrating another example of the input and output signals of the level measurement portions and of the error calculators of FIG. 1.

FIG. 9 is a block diagram illustrating another example configuration of the AGC device of FIG. 1.

FIG. 10 is a block diagram illustrating still another example of the level measurement portion of FIG. 5.

FIG. 11 is a block diagram illustrating still another example configuration of the AGC device of FIG. 1.

FIG. 12 is a block diagram illustrating an example configuration of an electronic device having the AGC device of FIG. 1.

### DETAILED DESCRIPTION

Example embodiments of the present invention will be described below with reference to the drawings, in which reference numbers having the same last two digits indicate components corresponding to one another, and indicate the same or similar components. A solid line between function blocks in a drawing represents an electrical connection.

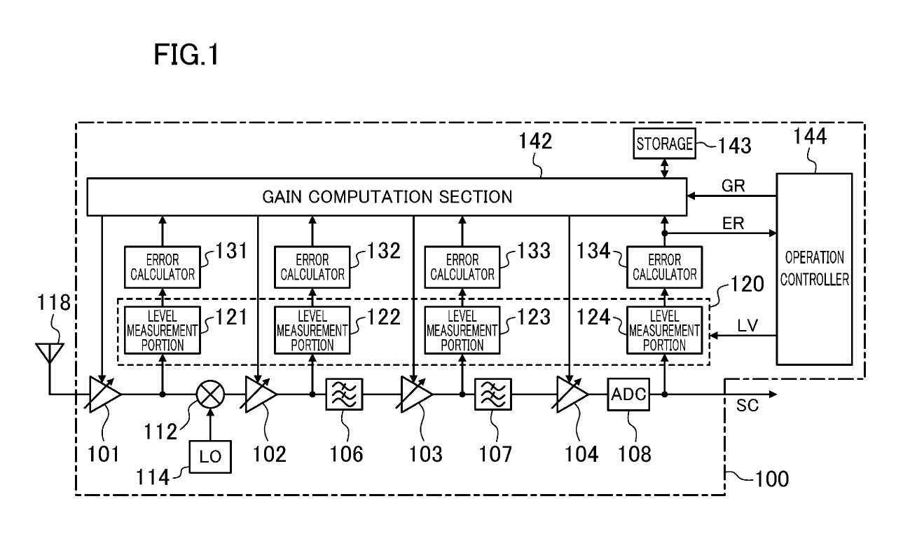

FIG. 1 is a block diagram illustrating an example configuration of an AGC device according to an embodiment of the present invention. The AGC device 100 of FIG. 1 includes a low noise amplifier (LNA) 101, variable gain amplifiers (VGAs) 102, 103, and 104, filters 106 and 107, an analog-to-digital converter (ADC) 108, a mixer 112, a local oscillator (LO) 114, a level measurement section 120, error calculators 131, 132, 133, and 134, a gain computation section 142, a storage 143, and an operation controller 144. The level measurement section 120 includes level measurement portions 121, 122, 123, and 124.

An antenna 118 receives a transmitted wave, and supplies the received signal to the LNA 101. The LNA 101 amplifies the received signal supplied from the antenna 118, and outputs the amplified signal to the mixer 112 and to the level measurement portion 121. The LO 114 generates a sinusoidal wave having a predetermined frequency, and outputs the sinusoidal wave to the mixer 112 as an LO signal. The mixer 112 multiplies the output signal of the LNA 101 with the LO signal, and outputs the obtained intermediate frequency (IF) signal to the VGA 102.

The VGA 102 amplifies the IF signal, and outputs the amplified signal to the filter 106 and to the level measurement portion 122. The filter 106 passes predetermined frequency components of the output signal of the VGA 102, and outputs the filtered signal to the VGA 103. The VGA 103 amplifies the output signal of the filter 106, and outputs the amplified signal to the filter 107 and to the level measurement portion 123. The filter 107 passes predetermined frequency components of the output signal of the VGA 103, and outputs the filtered signal to the VGA 104.

The VGA 104 amplifies the output signal of the filter 107, and outputs the amplified signal to the ADC 108. The ADC 108 converts the output signal of the VGA 104 from an analog format to a digital format, and outputs the obtained digital signal SC to a demodulator (not shown) and to the level measurement portion 124. The gains of the LNA 101 and the VGAs 102-104 are variable, and are set by the gain computation section 142. Thus, the level measurement portions 121, 122, 123, and 124 respectively correspond to the LNA 101 and the VGAs 102-104, which are amplifiers.

The level measurement portions 121-124 each measure the level of the output signal of the corresponding amplifier input thereto, and each output the measured level as an output signal. The error calculators 131, 132, 133, and 134 respectively correspond to the level measurement portions 121, 122, 123, and 124. The error calculators 131-134 each compare the level measured by the corresponding level measurement portion with one or more thresholds which are preset for the corresponding amplifier (the LNA 101 or the VGA 102, 103, or 104), and each output the comparison result as an error signal to the gain computation section 142. Each of the thresholds of the error calculators 131-134 is individually set to such a value that the corresponding amplifier will not saturate.

The gain computation section 142 updates one of the gains of the LNA 101 and the VGAs 102-104 at a time corresponding to a gain update signal GR, based on the error signals output from the respective error calculators 131-134. More specifically, the gain computation section 142 selects one amplifier whose gain is to be changed next time, based on the error signals output from the error calculators 131-134, the current gains of the respective amplifiers, and a predetermined order of controlling the amplifiers. The gain computation section 142 calculates the next gain to be set based on the error signal obtained from the output signal of the selected amplifier, and on the current gain of the selected amplifier, and then updates the gain of the selected amplifier with the calculated gain.

Here, it is important that the gain of the amplifier under control is calculated based on the error signal obtained from the output level of that amplifier. The operation controller 144 generates a level measurement signal LV based on the error signal ER output from the error calculator 134, and outputs the level measurement signal LV to the level measurement portions 121-124. In addition, the operation controller 144 generates the gain update signal GR based on the error signal ER, and outputs the gain update signal GR to the gain computation section 142.

A part or all of the LNA 101 and the VGAs 102-104 may each have the function of an attenuator. That is, the gain may be a negative value, and the LNA 101 and the VGAs 102-104 may attenuate the input signals, and output attenuated signals.

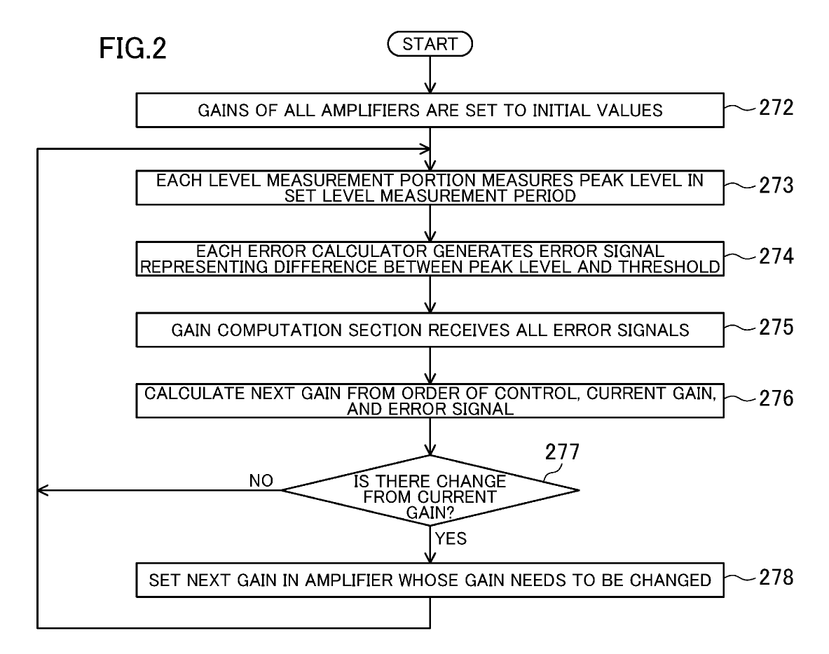

FIG. 2 is a flow chart illustrating an example flow of a process of the AGC device of FIG. 1. The process of FIG. 2 starts after power on or a channel selection. At step 272, the LNA 101 and the VGAs 102-104 of FIG. 1 set the respective gains to initial values. At step 273, the level measurement portions 121-124 each measure the peak level of the output signal of the corresponding amplifier in a level measurement period indicated by the level measurement signal LV.

At step 274, the error calculators 131-134 each generate the error signal representing the difference between the peak level measured at step 273 and the preset threshold. At step 275, the gain computation section 142 receives all the error signals. At step 276, the gain computation section 142 calculates the next gain to be set from the error signal, the gain currently set, and the order of control.

At step 277, the gain computation section 142 determines whether there is or is not a change between the current gain and the next gain based on the calculation result at step 276. If there is a change, the process proceeds to step 278; and if there is no change, the gain is unchanged and the process returns to step 273. At step 278, the gain computation section 142 sets the next gain in the amplifier whose gain needs to be changed. Then, the process returns to step 273, and the operations from step 273 to step 278 are repeated in a similar manner.

The sequence of operations from step 273 to step 278 are executed every predetermined period. This period is referred to as gain update period. If a signal having information in its amplitude, such as an amplitude modulation (AM) signal, is received, then the level measurement period needs to be set to a long period so as not to follow the characteristics of the modulated wave, while a rapid change in the level requires that the level measurement period be set to a short period so that the time to converge will be short. Thus, the operation controller 144 generates the gain update signal GR so that the gain update period depends on the error signal ER.

If the AGC device receives a signal including a guard interval, such as an orthogonal frequency division multiplexing (OFDM) signal, the operation controller 144 may receive a guard interval period signal indicating a guard interval period from the demodulator, and may generate the gain update signal GR so that the gain is changed in the guard interval period in order to synchronize with the guard interval period.

The gain update period may be fixed. The gain update period may be stored in a memory so as to be changeable depending on evaluation etc., and may subsequently be fixed.

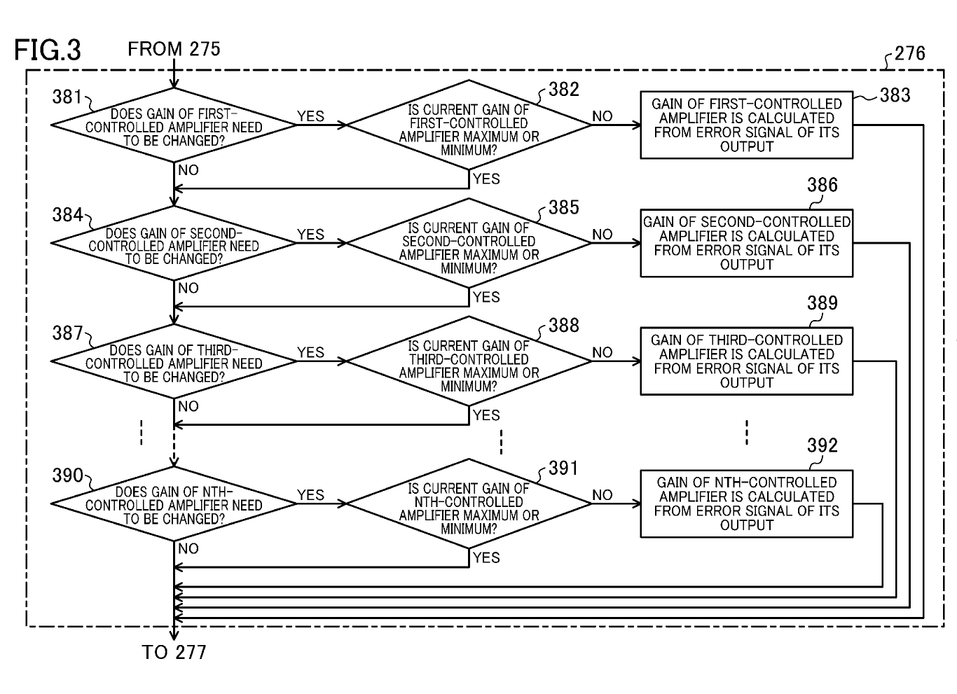

FIG. 3 is a flow chart illustrating step 276 of FIG. 2 in more detail, in which the next gain to be set is calculated. The amplifier on which the gain control is first performed is hereinafter referred to as first-controlled amplifier; the amplifier on which the gain control is performed second, second-controlled amplifier; the amplifier on which the gain control is performed third, third-controlled amplifier; and the amplifier on which the gain control is performed in an Nth operation, Nth-controlled amplifier.

First at step 381, the gain computation section 142 determines whether or not to change the gain of the first-controlled amplifier, based on the error signal corresponding to the output of the first-controlled amplifier. If the gain is to be changed, the process proceeds to step 382, and if the gain is to be unchanged, the process proceeds to step 384. At step 382, it is determined whether or not the gain currently set in the first-controlled amplifier is the maximum or minimum value that can be set in the amplifier. If the gain is the maximum or minimum value, the process proceeds to step 384; otherwise, the process proceeds to step 383. At step 383, the gain of the first-controlled amplifier is calculated from the error signal corresponding to the output thereof. The gains of the amplifiers other than the first-controlled amplifier are unchanged, and the process proceeds to step 277.

At step 384, the gain computation section 142 determines whether or not to change the gain of the second-controlled amplifier, based on the error signal corresponding to the output of the second-controlled amplifier. If the gain is to be changed, the process proceeds to step 385, and if the gain is to be unchanged, the process proceeds to step 387. At step 385, it is determined whether or not the gain currently set in the second-controlled amplifier is the maximum or minimum value that can be set in the amplifier. If the gain is the maximum or minimum value, the process proceeds to step 387; otherwise, the process proceeds to step 386. At step 386, the gain of the second-controlled amplifier is calculated from the error signal corresponding to the output thereof. The gains of the amplifiers other than the second-controlled amplifier are unchanged, and the process proceeds to step 277.

Operations for the third-through Nth-controlled amplifiers (steps 387-392) are performed in a similar manner.

Level measurement is performed on all the amplifier outputs in the level measurement period, and a gain update is performed on only one amplifier in each level measurement period. However, if the errors of all the amplifier outputs are less than or equal to a predetermined value, then the control is deemed to have converged, and the process of FIG. 3 is terminated without changing any gains of the amplifiers. If the gains of all the amplifiers are the maximum values and a gain needs to be further increased, or if, on the contrary, the gains of all the amplifiers are the minimum values and a gain needs to be further decreased, then the gain is deemed to have exceeded the range over which the gains are allowed to change, and the process of FIG. 3 is terminated without changing any gains of the amplifiers. Thus, performing a gain update only on one amplifier in each level measurement period allows the control to stably converge.

The storage 143 is a rewritable memory, and stores the order of controlling amplifiers such as the LNA 101 and the VGAs 102-104, and the maximum and minimum values of the gains of the respective amplifiers. The order of control and the values stored in the storage 143 are rewritten depending on the type of the received signal. The gain computation section 142 may read and use the order of controlling amplifiers and the maximum and minimum values of the gains of the respective amplifiers from the storage 143. In such a case, the AGC device 100 can easily provide optimum control for each type of modulated signals if the AGC device 100 receives multiple types of modulated signals, such as those having different frequencies or those generated by different modulation techniques. Similarly, the AGC devices described below may include the storage 143, and a gain computation section of each of the AGC devices may read and use the order of controlling amplifiers and the maximum and minimum values of the gains of the respective amplifiers. The AGC device 100 does not necessarily need to include the storage 143.

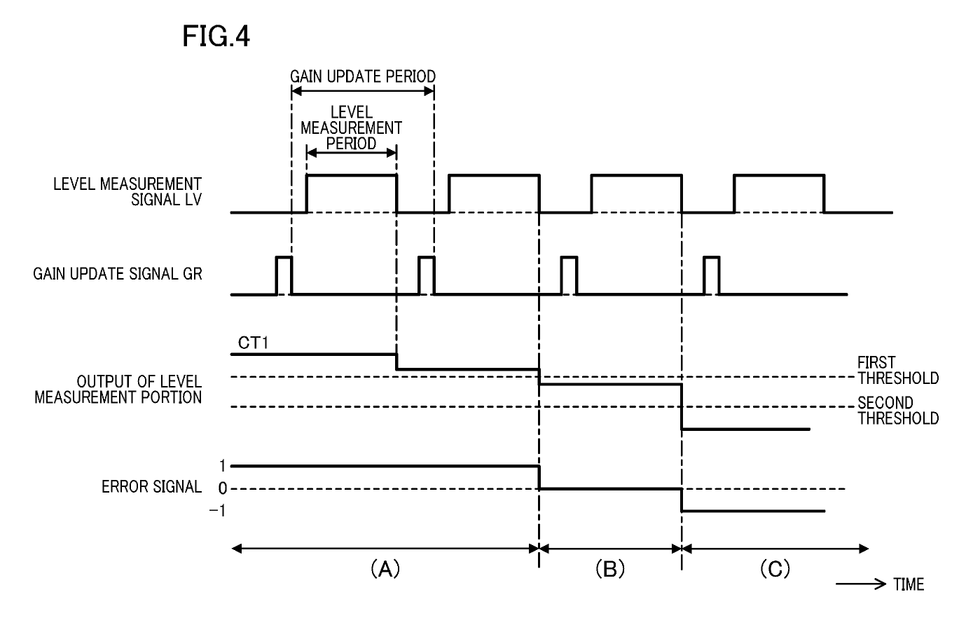

FIG. 4 is a timing diagram illustrating an example of the input and output signals of the level measurement portions and of the error calculators of FIG. 1. FIG. 4 shows, from top to bottom, the level measurement signal LV, the gain update signal GR, the output of the level measurement portion 121, and the error signal output from the error calculator 131.

The operation controller 144 outputs the level measurement signal LV and the gain update signal GR as shown in FIG. 4. The level measurement portions 121-124 each measure the level of the output of the corresponding amplifier in a time period (level measurement period) during which the level measurement signal LV is at a high logic level (High). While the gain update signal GR is High, the gain computation section 142 receives the error signals output from all the error calculators 131-134, calculates the next gain to be set using these error signals, and set the results in the respective amplifiers (the LNA 101 and the VGAs 102-104).

In the example of FIG. 4, a first threshold and a second threshold, which is lower than the first threshold, are set in the error calculator 131. The error calculator 131 compares the output signal of the level measurement portion 121 input thereto, which is a signal for comparison, with the first and the second thresholds. During the time period “A,” the value of the output signal is higher than the first threshold, and the error calculator 131 outputs “1” as the error signal. During the time period “B,” the value of the output signal is between the first and the second thresholds, and the error calculator 131 outputs “0” as the error signal. During the time period “C,” the value of the output signal is lower than the second threshold, and the error calculator 131 outputs “−1” as the error signal.

The gain computation section 142 decreases the gain of the LNA 101 corresponding to the level measurement portion 121 by a predetermined amount if the error signal is “1,” makes no changes to the gain if the error signal is “0,” and increases the gain by a predetermined amount if the error signal is “−1.” The other level measurement portions 122-124, the other error calculators 132-134, and the VGAs 102-104 also operate in a manner similar to what is shown in FIG. 4.

Although step control is more suitable for the gain control over the LNA 101 and the VGAs 102-104 by the gain computation section 142, linear control may be used. If linear control is provided, the gain is changed with a constant step size to simulate step control. Here, step control is discrete control of the gain, which is, for example, provided by switching resistors determinative of the gain by a switch in an inverting amplifier circuit having an operational amplifier, or by switching resistors or capacitors by a switch in a voltage-dividing circuit having resistors or capacitors. Linear control is continuous control of the gain, which is, for example, provided in an inverting amplifier circuit by using drain-to-source resistance of a MOS transistor as the resistance determinative of the gain (by changing the resistance value by the gate voltage), or by using a variable-capacitance diode as a capacitor (by changing the capacitance value by the voltage supplied).

It is preferable that the difference between the first and the second thresholds be twice or larger than the step size of the change in gain of each of the LNA 101 and the VGAs 102-104. For example, in an amplifier in which the gain can be set with a step size of 1 dB, the difference between the first and the second thresholds set in the corresponding error calculator is set to 2 dB. In doing so, a small variation in the step size of the change in gain of an amplifier or a small variation in the difference between the two thresholds due to device variations etc. does not cause the output of the level measurement portion to exceed both the first and the second thresholds at one time when the gain changes by one step size, but causes the output of the level measurement portion to be a value between the first and the second thresholds at least once. Thus, no oscillation phenomena occur such that the output of the level measurement portion repeatedly changes between a value at or above the first threshold and a value at or below the second threshold.

A third threshold higher than the first threshold and a fourth threshold lower than the second threshold may be further set in the error calculator 134. In such a case, the error calculator outputs, to the operation controller 144, a signal indicating that the gain update interval and the level measurement period should be decreased when the output of the level measurement portion is higher than the third threshold or lower than the fourth threshold, and outputs, to the operation controller 144, a signal indicating that the gain update interval and the level measurement period should be increased when the output of the level measurement portion is lower than the third threshold and higher than the fourth threshold. The operation controller 144 generates the gain update signal GR and the level measurement signal LV so as to change the gain update interval and the level measurement period based on this signal. The first and the second thresholds or the first through the fourth thresholds may be set in the error calculators 131-133, and the error calculators 131-133 may operate in a manner similar to the error calculator 134.

In general, an envelope detector circuit is used as each circuit of the level measurement portions 121-124 when the frequency of the input signal is high, while an operational circuit which calculates √(I²+Q²) from an I signal and a Q signal after analog-to-digital conversion is used when the frequency is low. An envelope detector circuit is a circuit which outputs an envelope of the input signal, and outputs a signal dependent on the level of the input signal. Either envelope detector circuits or operational circuits which calculate √(I²+Q²), or any combination thereof, may be used as the circuits of the level measurement portions 121-124. Other circuits may also be used as the level measurement portions, and some examples will be described below.

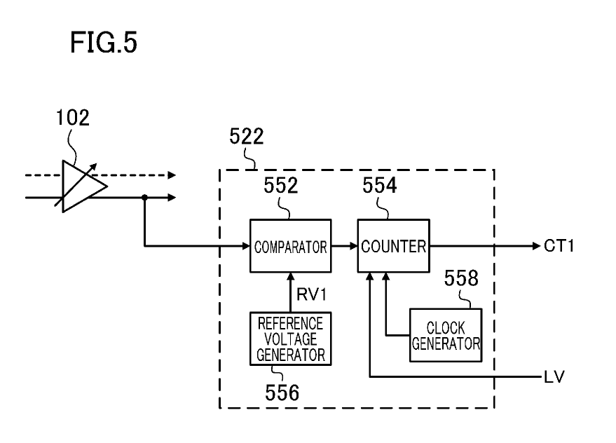

FIG. 5 is a block diagram illustrating an example configuration of the level measurement portions of FIG. 1. The level measurement portion 522 of FIG. 5 is suitable for measuring the level of a signal having a relatively low frequency which is, for example, lower than or equal to 10 MHz (e.g., down-converted intermediate frequency (IF) signal). The level measurement portion 522 of FIG. 5 is used as at least one of the level measurement portion 122 or 123 of FIG. 1. The level measurement portion 522 receives the output of the VGA 102 when used as the level measurement portion 122, and receives the output of the VGA 103 when used as the level measurement portion 123. Here, as an example, the case in which the level measurement portion 522 is used as the level measurement portion 122 will be described.

The level measurement portion 522 includes a comparator 552, a counter 554, a reference voltage generator 556, and a clock generator 558. The reference voltage generator 556 generates and outputs a reference voltage RV1. The clock generator 558 generates and outputs a clock CL. The comparator 552 compares the output signal of the VGA 102 with the reference voltage RV1, and outputs a signal at a level of High if the voltage of the output signal of the VGA 102 is higher, and otherwise, outputs a signal at a low logic level (Low).

The counter 554 is reset at a rising edge of the level measurement signal LV, and counts up at rising or falling edges of the clock while the output signal of the comparator 552 is High. Therefore, the counter 554 outputs a count value CT1 corresponding to the duration of the time period (High period) during which the output signal of the comparator 552 is High in the level measurement period. If the output signal of the VGA 102 is a differential signal, then the comparator 552 compares one of the two signals forming the differential signal with the reference voltage RV1.

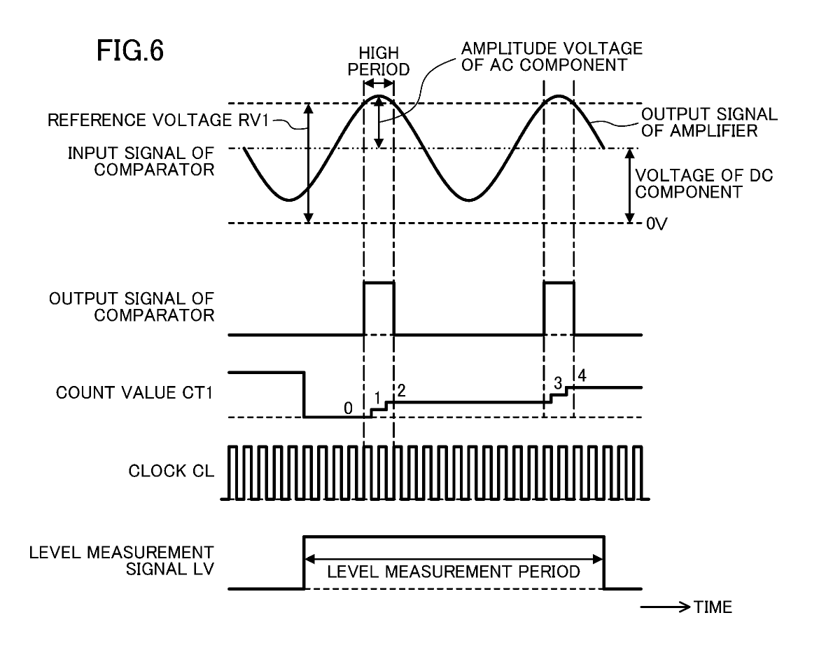

FIG. 6 is an illustrative diagram which illustrates the count value etc. in the level measurement portion of FIG. 5. FIG. 6 shows, from top to bottom, the input signal of the comparator 552, the output signal of the comparator 552, the count value CT1, the clock CL, and the level measurement signal LV.

As shown in FIG. 6, the counter 554 counts up at falling edges of the clock CL while the output signal of the VGA 102 is higher than the reference voltage RV1 in the level measurement period. Here, if the signal input from the VGA 102 to the comparator 552 is a sinusoidal wave, for example, having an alternating current (AC) component of an amplitude voltage of 0.5 V and a direct current (DC) component of a voltage of 1 V, and if the reference voltage RV1 is 1.6 V, then the output of the comparator 552 is always Low. If the reference voltage RV1 is 1.4 V, then the output of the comparator 552 alternates between High and Low. In this case, focusing on one cycle of the input signal to the comparator 552 (i.e., the output signal of the VGA 102), the ratio of the High period is 14.3% of one cycle.

Such a ratio of the High period to one cycle of the input signal to a level measurement portion is hereinafter referred to as threshold excess ratio. Reducing the threshold excess ratio causes the reference voltage RV1 to approach the peak level of the signal. Accordingly, identifying the duration of a High period allows the amplitude to be estimated, and thus measuring the duration of a High period can be deemed to be almost equivalent to measuring the peak level. The level measurement portion 522 outputs the duration of a High period to the corresponding error calculator as the level of the output signal of the corresponding amplifier. The Equation 1 to calculate the reference voltage from the threshold excess ratio can be expressed as follows:

Reference Voltage=Amplitude Voltage of AC Component·sin(2·π·(¼−Threshold Excess Ratio/100/2))+Voltage of DC Component (Eq. 1)

where the unit of the threshold excess ratio is percent.

In practice, a level measurement portion receives a signal having various frequencies, and thus the duration of a High period of every cycle cannot be measured. Accordingly, the level measurement period is set to a significantly longer time than the expected one cycle of the input signal. In addition, since the duration of the High period is measured in effect in units of the clock period, the frequency of the clock needs to be higher than that of the input signal.

The error calculator 132, or other corresponding error calculator, compares the count value CT1 output from the corresponding level measurement portion 522 with the first threshold and the second threshold, which is lower than the first threshold. For example, if the reference voltage RV1 is set so that the duration of the High period of the output of the comparator 552 is 10% of one cycle of the input signal to the level measurement portion 522, the first threshold is a count value equivalent to 5% of the level measurement period, and the second period is a count value equivalent to 15% of the level measurement period. For example, the error calculator 132, or other corresponding error calculator, outputs “1” if the count value CT1 output from the level measurement portion 522 is greater than the first threshold of the error calculator; “0” if the count value CT1 is less than the first threshold and greater than the second threshold; and “−1” if the count value CT1 is less than the second threshold (see FIG. 4). The gain computation section 142 determines that the gain should be decreased if “1” is received, that the gain should not be changed if “0” is received, and that the gain should be increased if “−1” is received.

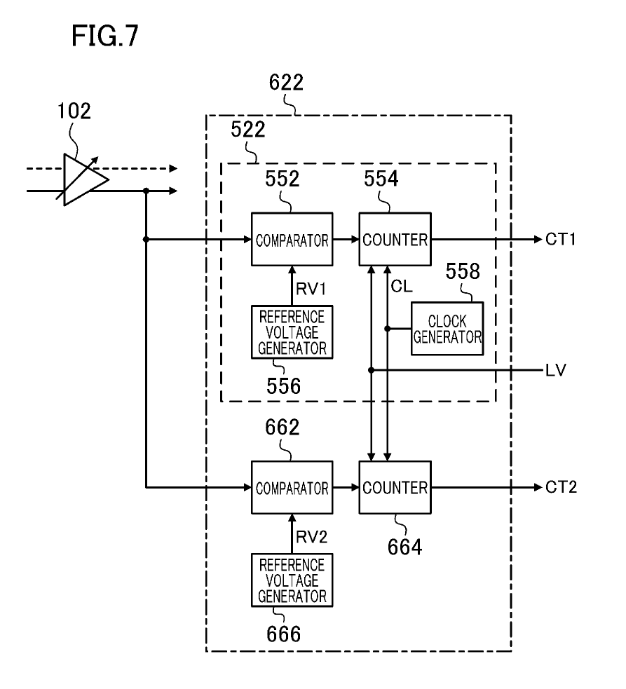

FIG. 7 is a block diagram illustrating a variation of the level measurement portion 522 of FIG. 5. In the level measurement portion 522 of FIG. 5, the ranges within which the first and the second thresholds of the error calculator can be set is reduced as the threshold excess ratio approaches 0% or 100%. Thus, if it is desired that the threshold excess ratio be near 0% or 100%, the level measurement portion 622 of FIG. 7 is used as the level measurement portions of FIG. 1.

The level measurement portion 622 of FIG. 7 further includes a comparator 662, a counter 664, and a reference voltage generator 666 in addition to the level measurement portion 522. For example, a first reference voltage RV1 is set to a voltage such that the threshold excess ratio will be 10% when the level of the signal input from an amplifier, such as the VGA 102, to the level measurement portion 622 is 0.9 V, and a second reference voltage RV2 is set to a voltage such that the threshold excess ratio will be 10% when the level of this signal is 0.8 V.

Under this condition, a first count value CT1 output by the counter 554 of FIG. 7 and a second count value CT2 output by the counter 664 are input to the error calculator 132 etc. corresponding to the level measurement portion 622, and the error calculator compares each of the count values with a threshold. The threshold is a count value equivalent to 10% of the level measurement period (equivalent to a threshold excess ratio of 10%). That is, if the level measurement portion 622 of FIG. 7 is used, only one threshold is needed for the corresponding error calculator.

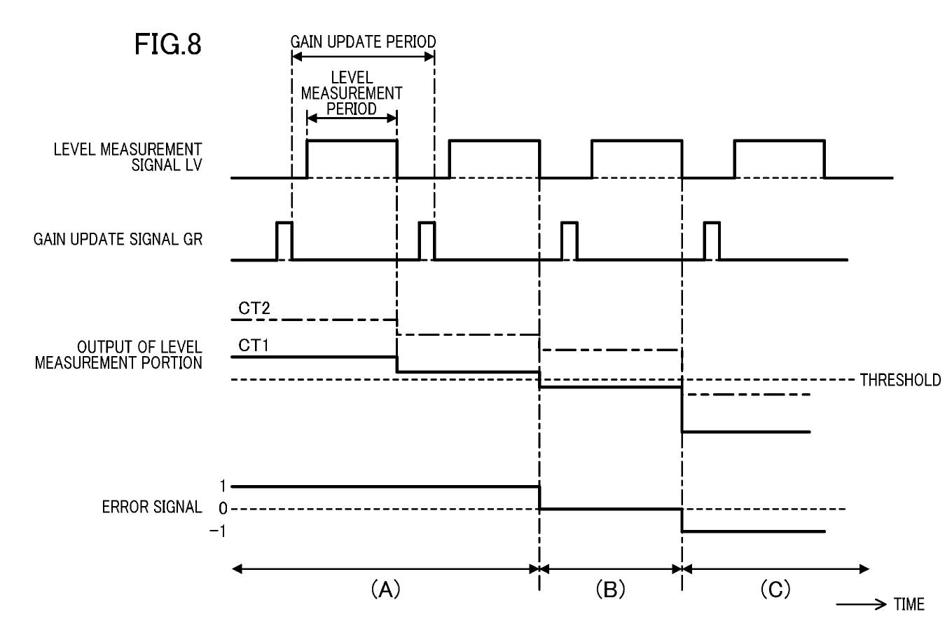

FIG. 8 is a timing diagram illustrating another example of the input and output signals of the level measurement portions and of the error calculators of FIG. 1. FIG. 8 illustrates a case in which the level measurement portion 622 of FIG. 7 is used as one or more level measurement portions of FIG. 1. For example, the error calculator 132, or other corresponding error calculator, outputs “1” if the first count value CT1 is greater than the threshold of the error calculator; “0” if the first count value CT1 is less than the threshold and the second count value CT2 is greater than the threshold; and “−1” if the second count value CT2 is less than the threshold.

In this way, increasing the number of comparators in the level measurement portion, and setting the respective reference voltages to different voltages is equivalent to increasing the number of thresholds of an error calculator. Thus, the threshold excess ratio can be set as desired.

The level measurement portions 522 etc. may each include a digital-to-analog converter (DAC), and the reference voltage may be generated by the DAC. In such a case, the threshold can be set to any desired value using a register which outputs a value to the DAC, and accordingly the threshold can easily be adjusted, for example, when a characteristic of the circuit has changed due to device variations, or when the required characteristics of the receiver are changed.

According to the configurations of FIGS. 5 and 7, the comparator 552 or 662 compares the output signal of the amplifier with the reference voltage, and measures the peak level based on the duration of the High period in the level measurement period. With this method, the peak level of a signal having a low frequency which is, for example, lower than or equal to 10 MHz can be easily measured with a simple circuit. In addition, since charging/discharging of capacitors is not performed, the response characteristic of the level measurement portion has only small effects on the response characteristic of the AGC device. Particularly according to the circuit of FIG. 5, the circuit area and the power consumption can be reduced.

The error calculators 132 etc. may each obtain the ratio of the count value CT1 or CT2 to the count value corresponding to the level measurement period, and compare the obtained value with the threshold. In this case, the error calculator 132, or other corresponding error calculator, uses a predetermined value of threshold excess ratio itself as the threshold. The operation of obtaining the ratio of the count value CT1 or CT2 may be performed by the level measurement portion 522 or 622.

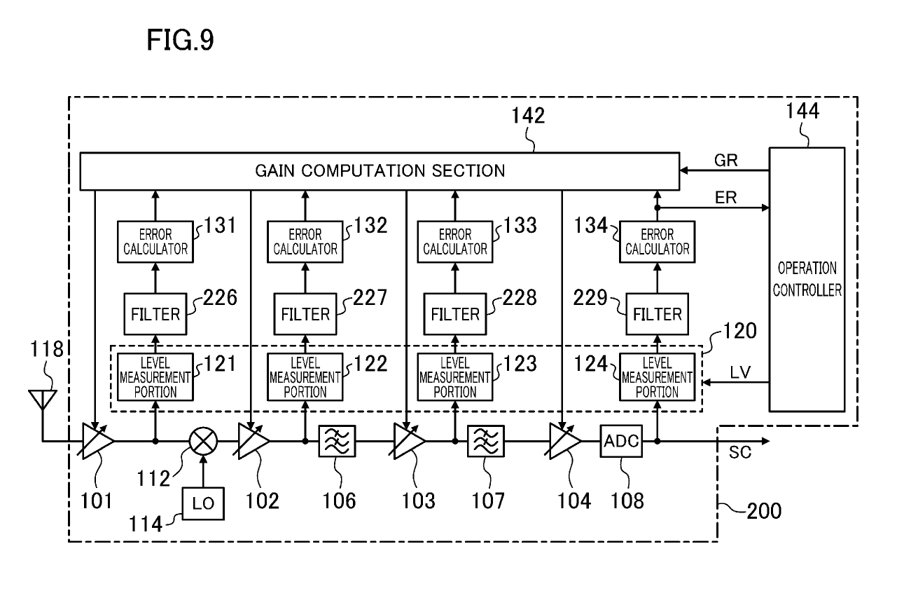

FIG. 9 is a block diagram illustrating another example configuration of the AGC device of FIG. 1. The AGC device 200 of FIG. 9 further includes low-pass filters 226, 227, 228, and 229, but is otherwise configured similarly to the AGC device 100 of FIG. 1. The filter 226 smoothes the output of the level measurement portion 121, and outputs the result to the error calculator 131. The filter 227 smoothes the output of the level measurement portion 122, and outputs the result to the error calculator 132. The filter 228 smoothes the output of the level measurement portion 123, and outputs the result to the error calculator 133. The filter 229 smoothes the output of the level measurement portion 124, and outputs the result to the error calculator 134. The filters 226-229 smooth the outputs by, for example, calculating moving averages.

According to the AGC device 200 of FIG. 9, even when the output signals of the level measurement portions 121-124 vary due to noise etc., smoothing operations by the filters 226-229 allow variations in the gains of the amplifiers (the LNA 101 and the VGAs 102-104) to be reduced. The AGC device 200 may include only a part of the filters 226-229.

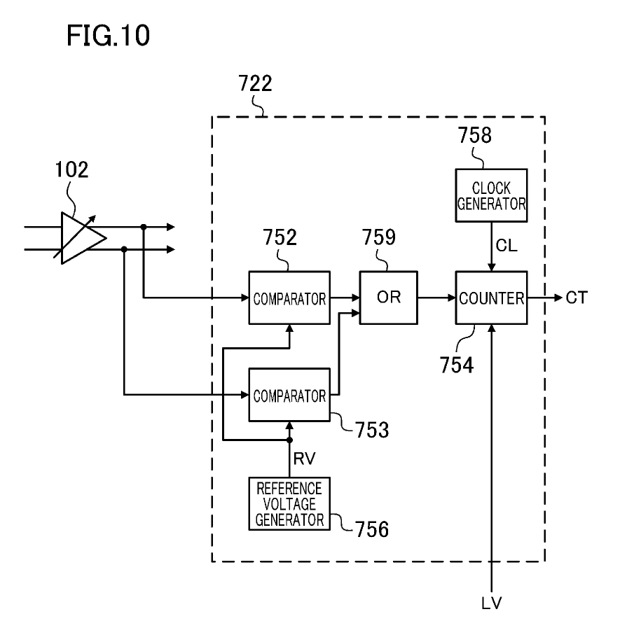

FIG. 10 is a block diagram illustrating still another example of the level measurement portion of FIG. 5. The level measurement portion 722 of FIG. 10 is used when the output signal of the amplifier such as VGA 102 is a differential signal. The level measurement portion 722 of FIG. 10 includes comparators 752 and 753, a counter 754, a reference voltage generator 756, a clock generator 758, and an OR circuit 759. The reference voltage generator 756 generates and outputs a reference voltage RV. The clock generator 758 generates and outputs a clock CL.

The comparator 752 receives one of the two signals forming the differential signal output from the VGA 102, and the comparator 753 receives the other one of the two signals. The comparators 752 and 753 respectively compare the input signals with the reference voltage RV, and output the comparison results to the OR circuit 759. The OR circuit 759 performs a logical OR operation on the two input comparison results, and outputs the result to the counter 754. The counter 754 is reset at a rising edge of the level measurement signal LV, counts up at rising or falling edges of the clock while the output signal of the OR circuit 759 is High, and outputs a count value CT.

That is, the counter 754 counts up while one of the two signals forming the differential signal is higher than the reference voltage RV and while the other one of the two signals forming the differential signal is higher than the reference voltage RV. That is, the situation shown in FIG. 10 is equivalent to measuring the absolute value of the output signal of the amplifier as the level of the input signal. With the configuration of FIG. 10, a level measurement portion which is less affected by the duty cycle of the output signal of the amplifier can be achieved.

Note that, if the circuit of FIG. 5, FIG. 7, or FIG. 10 is used as the level measurement portions 122 and 123, and the level measurement period is changed depending on the error signal, then the operation controller 144 informs the error calculators 131-134 of the updated level measurement period, and the error calculators 131-134 each set the count value corresponding to the threshold excess ratio with respect to the updated level measurement period as the threshold.

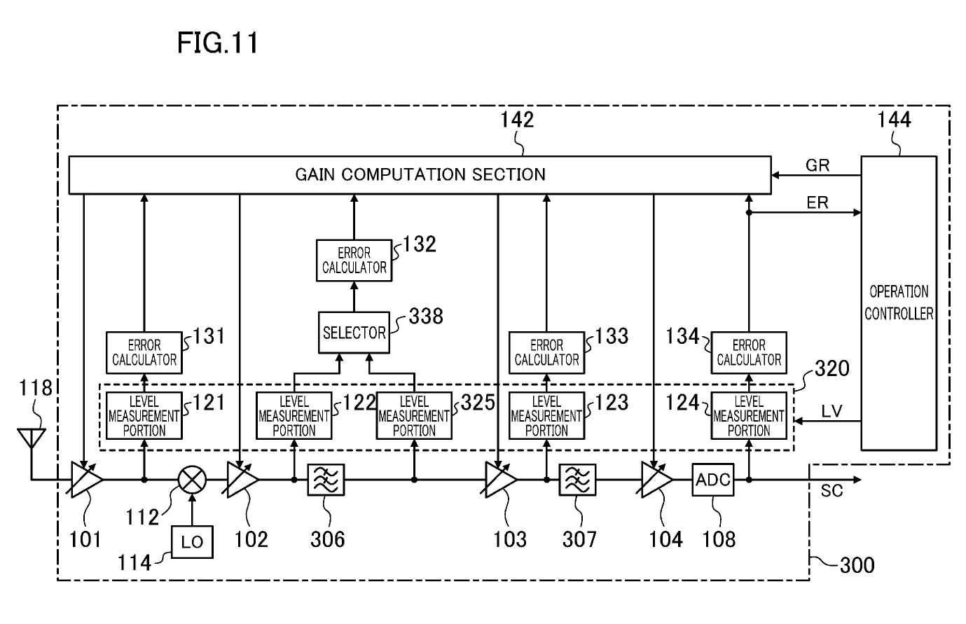

FIG. 11 is a block diagram illustrating still another example configuration of the AGC device of FIG. 1. The AGC device 300 of FIG. 11 includes filters 306 and 307 and a level measurement section 320 instead of the filters 106 and 107 and the level measurement section 120, and further includes a selector 338, but is otherwise configured similarly to the AGC device of FIG. 1. The level measurement section 320 further includes a level measurement portion 325 as a filter-output measurement portion, but is otherwise configured similarly to the level measurement section 120 of FIG. 1.

The filters 306 and 307 are configured together to provide a desired filter characteristic, and the gain of the center frequency of a desired signal is 0 dB. For example, a fourth-order filter is divided into two second-order filters, and the two filters are respectively used as the filters 306 and 307. Focusing on the respective frequency characteristics of the filters 306 and 307, a frequency exists which causes the gain of an interference signal to be higher than that of the desired signal, and thus an input of an interference signal having such a frequency causes the distortion to increase.

In order to avoid such a phenomenon, the level measurement portions 122 and 325 respectively measure the signal levels of the input and the output signals of the filter 306, and respectively output signals representing the measured values. The selector 338 selects and outputs a larger one of the outputs of the level measurement portions 122 and 325, that is, the larger measured value. The error calculator 132 outputs the difference between the output signal of the selector 338 and a set value to the gain computation section 142.

That is, the output of the selector 338 converges in such a way that the filter output remains constant while a signal having a frequency which causes the gain of the filter 306 to be greater than or equal to 0 dB is input, and converges in such a way that the filter input remains constant while a signal having a frequency which causes the gain of the filter 306 to be less than or equal to 0 dB is input. The level measurement signal LV output from the operation controller 144 is input to all of the level measurement portions 121-124 and 325 of the level measurement section 320.

According to such a configuration, measuring the signal levels before and after a filter, and then providing a gain control using the larger value causes the output level of the filter to become or fall below a predetermined level even if a signal having a frequency which causes a high filter gain is input, thereby allowing reduction in distortion performance to be reduced.

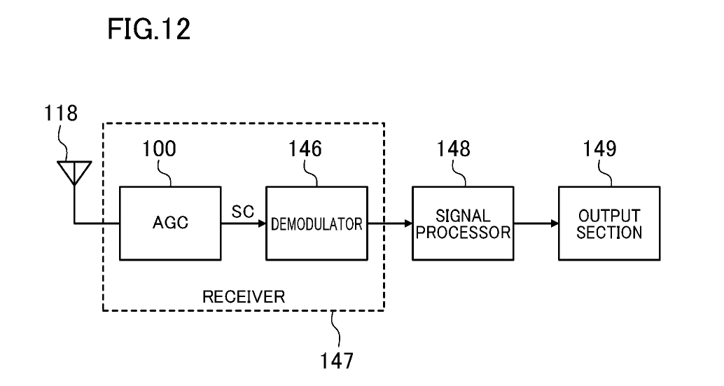

FIG. 12 is a block diagram illustrating an example configuration of an electronic device having the AGC device of FIG. 1. The electronic device of FIG. 12 includes a receiver 147, a signal processor 148, and an output section 149. The receiver 147 includes the AGC device 100 of FIG. 1 and a demodulator 146. Examples of the electronic device of FIG. 12 include a radio receiver set and a television receiver set.

The demodulator 146 demodulates a signal SC output from the AGC device 100, and outputs a demodulated signal. The signal processor 148 performs predetermined signal processing, such as decoding or amplification, on the demodulated signal output from the demodulator 146, and outputs a processed signal. The output section 149 is, for example, a display panel or a speaker, and at least displays video represented by the signal which has been processed by the signal processor 148, or outputs audio represented by the signal which has been processed by the signal processor 148. In the electronic device of FIG. 12, the AGC device 200 of FIG. 9 or the AGC device 300 of FIG. 11 may be used instead of the AGC device 100.

Each function block described herein can typically be implemented in hardware. For example, each function block can be formed on a semiconductor substrate as a part of an integrated circuit (IC). Here, the term IC includes large-scale integrated circuit (LSI), application-specific integrated circuit (ASIC), gate array, field programmable gate array (FPGA), etc. As another alternative, a part or all of each function block can be implemented in software. For example, such a function block can be implemented by a processor and a program executed by the processor. In other words, each function block described herein may be implemented in hardware, software, or any combination of hardware and software.

As described above, the automatic gain control devices according to the embodiments of the present invention can each effectively utilize the dynamic range of the receiver, and improve the reception performance of the receiver; and accordingly the present invention is useful for receivers in radio sets and television sets, etc.

The many features and advantages of the invention are apparent from the detailed specification and, thus, it is intended by the appended claims to cover all such features and advantages of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. An automatic gain control device, comprising:
a plurality of amplifiers cascaded, each having a variable gain;
a plurality of level measurement portions respectively corresponding to the plurality of amplifiers, where each of the plurality of level measurement portions is configured to measure a level of an output signal of a corresponding one of the amplifiers in a level measurement period indicated by a level measurement signal;
a plurality of error calculators respectively corresponding to the plurality of level measurement portions, where each of the plurality of error calculators is configured to compare a level measured by a corresponding one of the level measurement portions with a first threshold which is set so that a corresponding one of the amplifiers will not saturate, and to output a comparison result as an error signal;
a gain computation section configured to update one of the gains of the plurality of amplifiers at a time corresponding to a gain update signal, based on the error signals output from the respectively corresponding error calculators; and
an operation controller configured to generate the level measurement signal and the gain update signal based on a part of the error signals output from the plurality of error calculators.

2. The automatic gain control device of claim 1, wherein
the first threshold and a second threshold, which is lower than the first threshold, are set in at least one of the plurality of error calculators,
the at least one of the error calculators in which the first and the second thresholds are set compares a signal for comparison input thereto with the first and the second thresholds, and outputs a comparison result as the error signal, and
the gain computation section provides control so as to decrease a gain of at least one of the amplifiers corresponding to the at least one of the error calculators if the error signal of the at least one of the error calculators indicates that the signal for comparison is higher than the first threshold, and to increase the gain if the error signal of the at least one of the error calculators indicates that the signal for comparison is lower than the second threshold.

3. The automatic gain control device of claim 2, wherein
in addition to the first and the second thresholds, a third threshold higher than the first threshold and a fourth threshold lower than the second threshold are set in at least one of the plurality of error calculators,
the at least one of the error calculators in which the first through the fourth thresholds are set compares a signal for comparison input thereto with the third and the fourth thresholds, and outputs, as the error signal, a signal indicating that a gain update interval and the level measurement period should be decreased when the signal for comparison is higher than the third threshold or lower than the fourth threshold, and a signal indicating that the gain update interval and the level measurement period should be increased when the signal for comparison is lower than the third threshold and higher than the fourth threshold, and
the operation controller generates the gain update signal and the level measurement signal so as to change the gain update interval and the level measurement period based on the error signal of the at least one of the error calculators in which the first through the fourth thresholds are set.

4. The automatic gain control device of claim 2, wherein
a difference between the first and the second thresholds is twice or larger than a step size of a change in gain of each of the plurality of amplifiers.

5. The automatic gain control device of claim 1, wherein
if the automatic gain control device receives a signal including a guard interval, the operation controller generates the gain update signal so that the gain is updated in a guard interval period.

6. The automatic gain control device of claim 1, wherein
at least one of the plurality of level measurement portions outputs a value corresponding to a duration of a time period during which an output signal of a corresponding amplifier among the plurality of amplifiers is higher that a first reference voltage, as a level of the output signal of the corresponding amplifier, and
at least one of the error calculators corresponding to the at least one of the level measurement portions compares the level of the output signal of the corresponding amplifier with the first thresholds and a second threshold set in the at least one of the error calculators.

7. The automatic gain control device of claim 6, wherein
the at least one of the plurality of level measurement portions includes
a comparator configured to compare the output signal of the corresponding amplifier with the first reference voltage, and
a counter configured to count up while the output signal of the corresponding amplifier is higher than the first reference voltage, and to output a count value as the level of the output signal of the corresponding amplifier.

8. The automatic gain control device of claim 6, wherein
the at least one of the plurality of level measurement portions includes
a first comparator configured to compare one of signals forming a differential signal output from the corresponding amplifier with the first reference voltage, and to output a comparison result,
a second comparator configured to compare the other one of the signals forming the differential signal with the first reference voltage, and to output a comparison result,
an OR circuit configured to perform a logical OR operation on the comparison result of the first comparator and the comparison result of the second comparator, and
a counter configured to count up while one of the two signals forming the differential signal is higher than the first reference voltage or the other one of the two signals forming the differential signal is higher than the first reference voltage, and to output a count value as the level of the output signal of the corresponding amplifier.

9. The automatic gain control device of claim 1, wherein
at least one of the plurality of level measurement portions includes
a first comparator configured to compare the output signal of the corresponding amplifier with a first reference voltage,
a second comparator configured to compare the output signal of the corresponding amplifier with a second reference voltage,
a first counter configured to count up while the output signal of the corresponding amplifier is higher than the first reference voltage, and to output a count value as the level of the output signal of the corresponding amplifier, and
a second counter configured to count up while the output signal of the corresponding amplifier is higher than the second reference voltage, and to output a count value, and
outputs the count values of the first and the second counters as the levels of the output signal of the corresponding amplifier among the plurality of the amplifiers, and
at least one of the error calculators corresponding to the at least one of the level measurement portions compares the count values of the first and the second counters with the first threshold set in the at least one of the error calculators.

10. The automatic gain control device of claim 1, further comprising:
at least one filter corresponding to each of the plurality of level measurement portions,
wherein
the at least one filter smoothes an output of a corresponding level measurement portion among the plurality of level measurement portions, and outputs a result to a corresponding error calculator among the plurality of error calculators.

11. The automatic gain control device of claim 1, further comprising:
a filter provided between a first and a second amplifiers of the plurality of amplifiers, the filter being configured to output predetermined frequency components of a signal output from the first amplifier,
a filter-output measurement portion configured to measure a level of an output signal of the filter, and
a selector,
wherein
the selector selects a larger one of a value measured by a level measurement portion corresponding to the first amplifier and a value measured by the filter-output measurement portion, and outputs a selected one to one of the error calculators which corresponds to the first amplifier, and
the gain computation section controls a gain of the first amplifier based on an error signal output from the error calculator corresponding to the first amplifier.

12. The automatic gain control device of claim 1, further comprising:
a rewritable storage configured to store an order of controlling the plurality of amplifiers,
wherein
the gain computation section selects one amplifier whose gain is to be changed from the plurality of amplifiers based on the error signals output from the plurality of error calculators, on the gains of the plurality of amplifiers, and on the order of controlling the plurality of amplifiers read from the storage, calculates a next gain to be set based on an error signal obtained from an output signal of the selected amplifier and on a gain of the selected amplifier, and updates the gain of the selected amplifier with the next gain to be set.

13. An electronic device, comprising:
a receiver having the automatic gain control device of claim 1, and a demodulator configured to demodulate a signal amplified by the automatic gain control device, and to output a demodulated signal;
a signal processor configured to perform predetermined signal processing on the demodulated signal, and to output a processed signal; and
an output section configured to, at least
display video represented by the signal which has been processed by the signal processor, or
output audio represented by the signal which has been processed by the signal processor.
